(19) United States
(12) Patent Application Publication
(10) Pub. No.: US 2012/0104557 A1
(43) Pub. Date: May 3, 2012

(54) Method for manufacturing a group III nitride crystal, method for manufacturing a group III nitride template, group III nitride crystal and group III nitride template

(75) Inventors: Takehiro Yoshida, Tsuchiura (JP); Yuichi Oshima, Tsuchiura (JP); Tadayoshi Tsuchiya, Ishioka (JP)

(73) Assignee: Hitachi Cable, Ltd., Tokyo (JP)

(21) Appl. No.: 13/137,538

(22) Filed: Aug. 24, 2011

(30) Foreign Application Priority Data
Nov. 2, 2010 (JP) 2010-246048
Apr. 5, 2011 (JP) 2011-083404

(51) Int. Cl. C30B 25/00; H01B 1/02; H01L 29/20

(52) U.S. Cl. 257/615; 117/104; 252/508; 257/E29.089

(57) ABSTRACT

A method for manufacturing a group III nitride crystal includes a step of mixing a group III source material and ammonia in a reactor including quartz, and growing a group III nitride crystal on a support substrate by a vapor deposition. The group III source material is an organic metal source material containing Al. The organic metal source material is mixed with a hydrogen halide gas and the mixture of the organic metal source material and the hydrogen halide gas is supplied to the reactor.

The present application is based on Japanese Patent Application No.2010-246048 filed on Nov. 2, 2010 and Japanese Patent Application No.2011-83404 filed on Apr. 5, 2011, the entire contents of which are incorporated herein by reference.

### BACKGROUND OF THE INVENTION

1. Field of the Invention

The invention relates to a method for manufacturing a group III nitride crystal, a method for manufacturing a group HI nitride template, a group III nitride crystal and a group III nitride template.

2. Description of the Related Art

Aluminum nitride (AlN) has an extremely wide band gap of 6.2 eV. Accordingly, by forming a mixed crystal from GaN having a band gap of 3.4 eV and AlN at an arbitrary composition ratio (AlₓGa₁₋ₓN, where 0<x≦1), a crystal with a band gap of an arbitrary value between those of AlN and GaN can be obtained. Consequently, the application thereof as an ultraviolet light-emitting device or light receiving device is now under research.

Since a group III nitride semiconductor has a high saturated drift velocity, the application to a high-frequency power device is also under research. At present, an AlₓGa₁₋ₓN device using a hetero-substrate is studied. This is because it is difficult to fabricate the AlₓGa₁₋ₓN device using a homo-substrate. As for GaN, a single crystal substrate is widely distributed, which is produced by a Hydride Vapor Phase Epitaxy (HVPE) method. Compared with the fabrication of GaN, it is extremely difficult to fabricate an AlₓGa₁₋ₓN crystal by the HVPE method.

Further, while a crystal substrate which is formed of a conventional semiconductor source material such as Si, GaAs or the like is fabricated by crystallizing the melt, a group III nitride crystal is easily sublimated so that the melt cannot be obtained easily. Accordingly, a group III nitride substrate crystal is generally fabricated by a vapor deposition method.

In general, the HVPE method is a method of growing a crystal by flowing a hydrogen halide gas onto a group III nitride melt, thereby producing a halogenated gas to be conveyed into a growth region, and mixing ammonia which is supplied through a different system with the halogenated gas in the growth region. Such reaction is taken place in a reactor made of quartz. Heat treatment is conducted by a so-called hot wall method of applying heat by heaters provided around the reactor.

However, there is a disadvantage in that Al monohalide drastically erodes the quartz. This makes it difficult for the AlₓGa₁₋ₓN crystal to grow by the HVPE method.

Accordingly, as a method for manufacturing the AlₓGa₁₋ₓN crystal, specifically an AlN substrate, a sublimation method has been examined, and a high-quality AlN substrate is realized by the sublimation method. However, in the growth by the sublimation method, there is a disadvantage in that it is difficult to provide a larger diameter and therefore it is difficult to realize a substrate with a size suitable for a practical use. Accordingly, it has been much desired to establish the technique for growing the AlₓGa₁₋ₓN crystal by the HVPE method, in which it is relatively easier to provide the AlₓGa₁₋ₓN crystal with a larger diameter.

When a temperature in which the Al monohalide reacts with the hydrogen halide gas is higher than 700° C., Al monohalide tends to be generated preferentially to others. On the other hand, when the temperature is 700° C. or less, Al trihalide tends to be generated preferentially to others. Here, the Al trihalide does not erode the quartz. Therefore, the growth of the AlₓGa₁₋ₓN crystal by the HVPE method can be realized by utilizing this phenomenon (e.g., see Japanese Patent No. 3803788).

Further, instead of supplying the Al trihalide generated in the reactor, a technique of growing an AlₓGa₁₋ₓN crystal by the HVPE method by directly supplying a source material for the Al trihalide to the reactor is also proposed by Ken-ichi Eriguchi, et al., “MOVPE-like HVPE of ALN using solid aluminum trichloride source”, J. Crystal Growth 298 (2007), pp. 332-335.

Further, to utilize such crystal for a substrate, it is required to control electrical conductivity at all costs. Accordingly, it is necessary to dope appropriate impurity into the crystal.

Although a growth technique is different, in Metal Organic Vapor-Phase Epitaxy (MOVPE) method, as impurities for providing an AlGaN crystal or GaN crystal with an n-type conductivity, silicon (Si), carbon (C), germanium (Ge), tin (Sn), lead (Pb), sulfur (S), selenium (Se), and tellurium (Te) have been known, and as impurities for providing the AlGaN crystal or GaN crystal with a p-type conductivity, cadmium (Cd), beryllium (Be), magnesium (Mg), zinc (Zn), mercury (Hg) have been known (e.g., see Japanese Patent No. 3016241).

Further, it has been also known that a semi-insulation property can be provided by doping iron (Fe), Mg, or C to a Si-doped AlₓGa₁₋ₓN (including x=0, x=1) at a concentration of a tenth ( 1/10) of a Si concentration in the MOVPE method (e.g., see JP-A 2009-21362).

Still further, it has been also known that a semi-insulating gallium nitride crystal can be provided by doping transition metallic species in the HVPE method (e.g., see JP-T 2007-534580, i.e. Publication of Japanese translation of WO2005/008738).

### SUMMARY OF THE INVENTION

However, in the technique of using the Al trihalide to grow the AlN crystal, by-product such as NH₄Cl and the like is produced three times more in amount compared with the technique using the Al monohalide to grow the AlN crystal. Such by-product is normally strained by a filter provided in an exhaust line. However, when a thick film is grown to obtain a single crystal substrate, there are disadvantages in that a filter housing is immediately filled up and that the exhaust line is clogged in an upstream side of the filter.

Further, when an AlₓGa₁₋ₓN mixed crystal is grown, a similar problem arises although in a smaller degree. For example, the AlₓGa₁₋ₓN mixed crystal is grown in a conventional HVPE apparatus, the crystal growth is made possible by setting a heater at a temperature of 700° or less. In this case, however, Ga trihalide is produced at a higher rate compared with the case when the heater is set at a temperature higher than 700°. Therefore, the amount of by-product generated during the growth increases similarly. In addition, there is another disadvantage in that, in the HVPE method using the trihalide, the amount of the trihalide to be conveyed as the source material is one-third (⅓) compared with the amount of the hydrogen halide which is supplied to the reactor. Therefore, this technique is inefficient.

Further, the majority of the reactor and components of the reactor are made of quartz in the HVPE method. Therefore, even though a doping gas is not flown into the reactor intentionally, the quartz may function as a source and Si or O is automatically taken into the group III nitride crystal from an atmosphere in the reactor, so that the group III nitride crystal exhibits the n-type conductivity. Since a concentration of free electron in the crystal obtained at this time is determined by the concentration of Si or O taken in to the crystal, the result depends on circumstances such as a proportion of the quartz components used in the reactor, the growth rate of the crystal. Accordingly, there is a disadvantage in that it is difficult to precisely control the electrical conductivity for providing the group III nitride crystal with a semi-insulating property or p-type conductivity as well as the n-type conductivity.

Accordingly, an object of the invention is to provide a method for manufacturing a group III nitride crystal, a group III nitride template, a group III nitride crystal and a group III nitride template, which can suppress a damage in a reactor including quartz and suppress generation of by-product.

(1) According to a feature of the invention, a method for manufacturing a group III nitride crystal comprises:

mixing a group III source material and ammonia in a reactor comprising quartz; and

growing a group III nitride crystal on a support substrate by a vapor deposition,

wherein the group III source material comprises an organic metal source material containing Al, and the organic metal source material is mixed with a hydrogen halide gas and supplied to the reactor.

(2) In the method for manufacturing the group III nitride crystal, the organic metal source material containing Al may comprise trimethyl aluminum.

(3) In the method for manufacturing the group III nitride crystal, the hydrogen halide gas may be selected from the group consisting of a hydrogen chloride, a hydrogen bromide and a hydrogen iodide.

(4) In the method for manufacturing the group III nitride crystal, the support substrate may comprise a single crystal substrate comprising a single crystal of a material selected from the group consisting of a sapphire, a silicon, a silicon carbide and a gallium nitride.

(5) According to another feature of the invention, a method for manufacturing a group III nitride template comprises:

forming the group III nitride crystal as a buffer layer by the method according to the invention (1), and

forming a second group III nitride semiconductor layer on the buffer layer.

(6) In the method for manufacturing the group In nitride template, the second group III nitride semiconductor layer may comprise a composition of AlₓIn_{y}Ga_{1-x-y}N (0≦x≦1, 0≦y≦1, 0≦x+y≦1).

(7) According to a still another feature of the invention, a group III nitride crystal comprises:

carbon of 1×10¹⁶ cm⁻³ or more and less than 1×10²⁰ cm⁻³ in the group III nitride crystal,

wherein the carbon replaces a group V site,

wherein-other impurities acting as an acceptor in the group III nitride crystal is not contained.

(8) According to a further feature of the invention, a group III nitride template comprises:

a support substrate;

a buffer layer formed on the support substrate, the buffer layer comprising the III group nitride crystal according to the invention (7); and

a second group III nitride semiconductor layer formed on the buffer layer.

(9) In the group III nitride template, the second group III nitride semiconductor layer may comprise a composition of AlₓIn_{y}Ga_{1-x-y}N (0≦x≦1, 0≦y≦1, 0≦x+y≦1).

### Effect of the Invention

According to the invention, a method for manufacturing a group III nitride crystal, a method for manufacturing a group III nitride template, a group III nitride crystal and a group III nitride template is provided, in which a damage in a reactor comprising quartz can be suppressed and generation of by-product can be suppressed. Further, it is possible to provide the group III nitride crystal with n-type conductivity, p-type conductivity or semi-insulation property.

### BRIEF DESCRIPTION OF THE DRAWINGS

FIG. 1 is a schematic diagram showing a hot wall type HVPE apparatus to be used in a method for manufacturing a group III nitride crystal in an embodiment according to the invention;

FIG. 2 is a schematic diagram showing a cold wall type HVPE apparatus to be used in the method for manufacturing the group III nitride crystal;

FIG. 3 is a graph showing a relationship between a TMA partial pressure and an AlN growth rate;

FIG. 4 is a graph showing a relationship between the TMA partial pressure and a specific resistance in Example 1a;

FIG. 5 is a graph showing the relationship between the TMA partial pressure and Si and C concentration in a crystal in Example 1a;

FIG. 6 is a graph showing the result of X-ray diffraction (θ-2θ) measurement of an AlN crystal in Example 1a;

FIG. 7 is a graph showing the result of φ scan at a (10-11) plane of the AlN crystal in Example 1a;

FIG. 8 is a graph showing a relationship between the TMA partial pressure and a specific resistance in Example 1b;

FIG. 9 is a graph showing the relationship between the TMA partial pressure and a Si and C concentration in a crystal in Example 1b;

FIG. 10 is a graph showing a relationship between the TMA partial pressure and a specific resistance in Example 1c;

FIG. 11 is a graph showing the relationship between the TMA partial pressure and a Si and C concentration in a crystal in Example 1c;

FIG. 12 is a graph showing a relationship between an NH₃ partial pressure and a specific resistance in Example 1d;

FIG. 13 is a graph showing the relationship between the NH₃ partial pressure and a Si and C concentration in a crystal in Example 1c.

FIG. 14 is a graph showing a relationship between an GaCl partial pressure and an Al composition ratio x in an AlₓGa₁₋ₓN crystal in Example 2a; and

FIG. 15 is a schematic diagram showing an HVPE apparatus to be used in a method for manufacturing a group III nitride crystal, which further contains In (indium) source material.

### DETAILED DESCRIPTION OF THE PREFERRED EMBODIMENT

### Embodiment

Next, en embodiment according to the invention will be explained in more detail in conjunction with appended drawings.

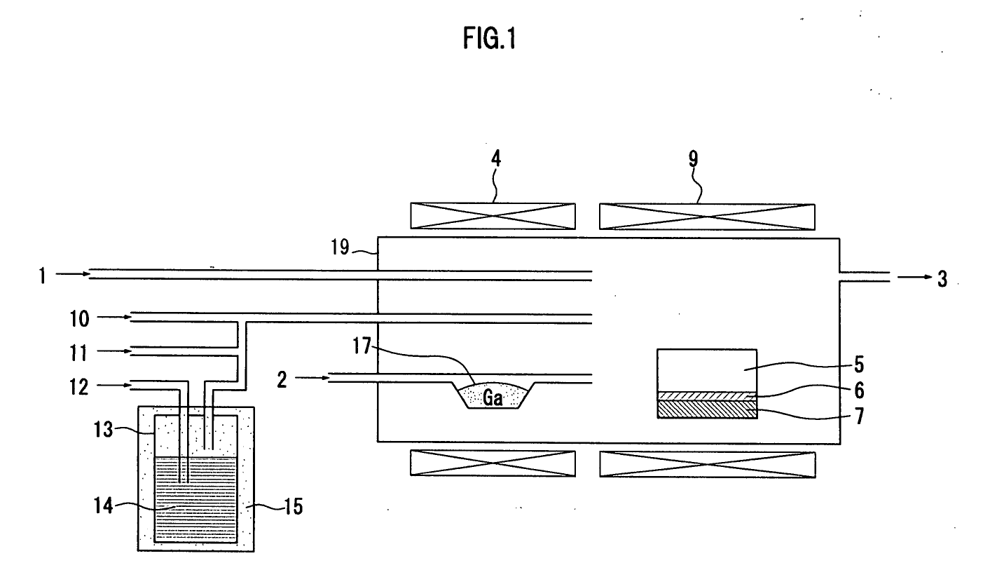

FIG. 1 shows a schematic diagram of a hot wall type HYPE apparatus to be used in a method for manufacturing a group III nitride crystal in the embodiment according to the invention.

The method for manufacturing a group III nitride crystal in the embodiment according to the invention is a method for manufacturing a group III nitride crystal by mixing a group III source material and ammonia in a reactor 19 which is made of quartz, and growing a group III nitride crystal on a support substrate 6 by a vapor phase epitaxy method, in which an organic metal containing Al as a group III source material is mixed with hydrogen halide gas, and supplied into the reactor 19, to manufacture the group III nitride crystal. The group III nitride crystal is e.g. an AlₓGa₁₋ₓN (where 0<x≦1) crystal.

The group III nitride crystal preferably contains carbon for 1×10¹⁶ cm⁻³ or more and less than 1×10²⁰ cm⁻³ in the crystal, in which the carbon replaces a group V site, and which does not contain other impurities acting as an acceptor (e.g., Mg, Be, Cd, Zn, Hg) in the group III nitride crystal.

More specifically, a temperature of a cylinder container 13 made of SUS (Steel Use Stainless), in which an organic metal source material 14 for Al is filled, is adjusted in a constant temperature reservoir 15 so as to obtain a desired vapor pressure. As the organic metal source material 14 for Al, a general organic metal source containing Al can be used. Trimethylaluminum (TMA) is the easiest material to deal with.

Next, the organic metal material 14 for Al is supplied to the reactor 19 after being bubbled with a bubbling gas 12. A gas supplied by bubbling is mixed with hydrogen halide gas 11 before the introduction into the reactor 19, and then conveyed by carrier gas 10 to a growth region (i.e. a region including a surface of the support substrate 6 provided on a susceptor 7) in the reactor 19. The hydrogen halide gas 11 is preferably a gas selected from the group consisting of a hydrogen chloride, a hydrogen bromide and a hydrogen iodide.

Further, a mixed gas 2 of hydrogen halide gas and carrier gas is supplied onto a surface of Ga melt 17 in contact with the surface of the Ga melt 17, to generate a Ga halide to be supplied to the growth region. Herein, a region including the surface of the Ga melt 17 is also referred to as “a Ga halide generating region” or “a source material generating region”. At this point, the temperature of the Ga halide generation region is controlled by a heater 4, and is preferably more than 700° C.

Next, in the growth region, the group III source materials and ammonia gas 1 are mixed on the support substrate 6 provided on the susceptor 7 made of graphite. Then, the AlₓGa₁₋ₓN is grown on the support substrate 6. As the support substrate 6, it is preferable to use a single crystal substrate made of a single crystal of a material selected from the group consisting of sapphire, silicon, silicon carbide, and gallium nitride. The temperature of the growth region is controlled by a heater 9. It is preferable that the temperature of the growth region is controlled to be within a temperature range of 1000° C. or more and 1100° C. or less.

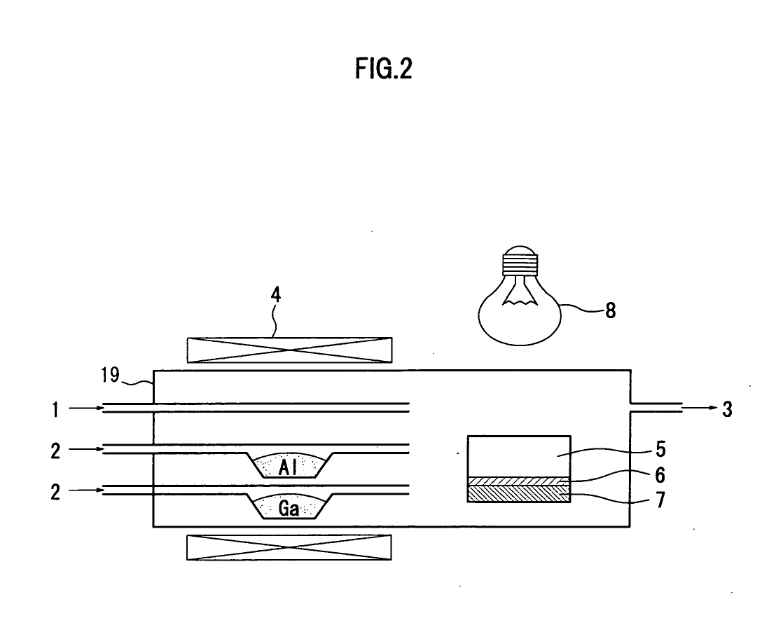

Instead of the hot wall type HVPE apparatus as shown in FIGS. 1, a cold wall type HVPE apparatus as shown in FIG. 2 may be used. At this time, the temperature of the susceptor 7 can be raised up to 1500° C.

As for the bubbling gas 12 and each carrier gas, it is preferable to use inactive gas (N₂, Ar, or He) or a mixed gas thereof.

In the present embodiment, it is extremely important that the organic metal source material of Al and the hydrogen halide gas are mixed and supplied into the reactor. Since the organic metal source material of Al is a Lewis acid and NH₃ is a Lewis base, when the organic metal source material of Al and NH₃ collide with each other, it does not contribute to the crystal growth since an adduct is easily formed by the collision. By supplying the mixed gas of the organic metal source material and hydrogen halide gas into the reactor after mixing, Al is conveyed to the growth region in the form of alkyl halide regardless of the temperature of the source material generating region and the growth region. Therefore, it is assumed that the organic metal source material and hydrogen halide gas contribute to the growth of the AlₓGa₁₋ₓN crystal without forming any adduct or incurring erosion of quartz.

Further, it is confirmed that Al conveyed in the form of the alkyl halide provides another important effect. It is confirmed that, when the-alkyl halide in which C is bonded to Al as the group HI source material is taken into the crystal, C enters into a group V site and acts as an acceptor securely. According to this phenomenon, it possible to control the electrical conductivity as desired (n-type, p-type, or semi-insulation), by adjusting the growth temperature and the growth rate of the Al composition in the group III nitride crystal. More specifically, it is possible to change the growth rate by adjusting a flow of TMA, a partial pressure of NH₃, a partial pressure of the hydrogen halide gas which is flown together with TMA). When the growth rate or NH₃ partial pressure is raised or the growth temperature is lowered, Si concentration originated from quartz component in the crystal is lowered, so that the compensation degree can be controlled.

It is known that C may act as an acceptor. JP-A 2009-21362 already discloses that C acts to compensate for donor's action, i.e. an acceptor, in the group III nitride crystal. On the other hand, Japanese Patent No. 3016241 and JP-T 2007-534580 describe that C acts as a donor in the group HI nitride crystal. In other words, C replaces a group V site in JP-A 2009-21362, whereas C replaces a group III site in Japanese Patent No. 3016241 and JP-T 2007-534580. It is assumed that the site which C replaces can be controlled by changing the growth condition. Neither Japanese Patent No. 3016241 nor JP-A 2009-21362 discloses the specific growth condition for C dope, i.e. as to under what condition the change of C action specifically occurs. Even a source material used in doping is not described in Japanese Patent No. 3016241 nor JP-A 2009-21362. From the disclosure of JP-A 2009-21362, it is understood that there is no relationship between the site to be replaced by C and the growth temperature.

Accordingly, the embodiment of the present invention is extremely novel and important, since the present invention provides a method for securely replacing the group V site with C.

### Effects of the Embodiment

In the method for manufacturing a group III nitride crystal according to the embodiment of the invention, the organic metallic gas of Al and the hydrogen halide are mixed and supplied into the reactor as the Al source material for growing an AlₓGa₁₋ₓN crystal (0<x≦1) by the HVPE method. Accordingly, it is possible to suppress damage in a reactor including quartz. Further, it is possible to grow the AlₓGa₁₋ₓN crystal (0<x≦1) by the HVPE method while suppressing the generation of a by-product. Still further, since the generation temperature of the Ga halide can be set similarly to the conventional method, the Ga monohalide can be mainly used for the growth. Further, it is possible to control the electrical conductivity such as n-type, p-type, semi-insulation.

### EXAMPLES

### Example 1a

A growth of a group III nitride crystal was conducted by using the HVPE apparatus shown in FIG. 1. TMA was used as the organic metal source material 14 of Al. The temperature of the constant temperature reservoir 15 was set to be 19° C. TMA was bubbled by N₂ as a bubbling gas 12, and mixed with HCl gas 11. Thereafter, the mixed gas was conveyed by the carrier gas 10 to a growth region. N₂ was used for the carrier gas 10 of a TMA+HCl line. A growth pressure was set to be the normal pressure.

In addition, only the carrier gas 2 (N₂) was supplied onto the Ga melt 17. Here, the temperature of the source material generating unit (i.e. the temperature of the Ga melt 17) was set to be 850° C.

In the growth region, an Al source material and the ammonia gas 1 were mixed on a c-plane sapphire substrate 6 (a diameter of 2 inches) mounted on the susceptor 7 made of graphite and heated at 1100° C., so that the AlN crystal (a diameter of 2 inches) was grown on the substrate 6.

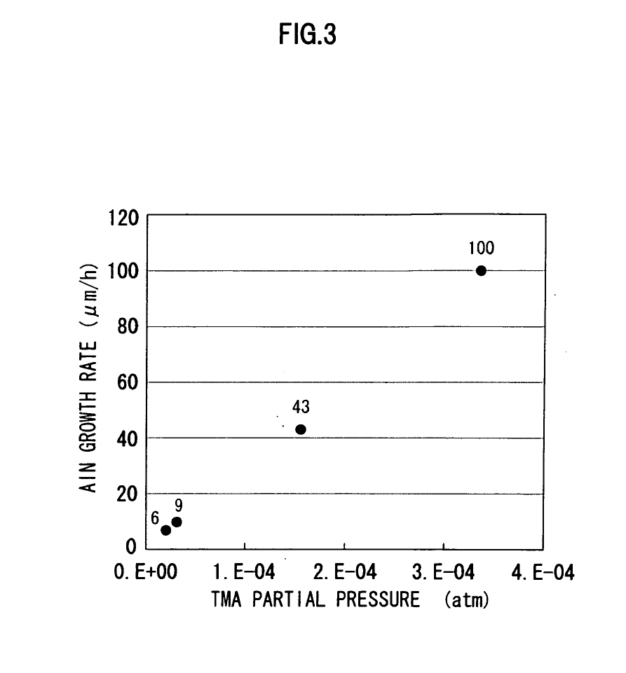

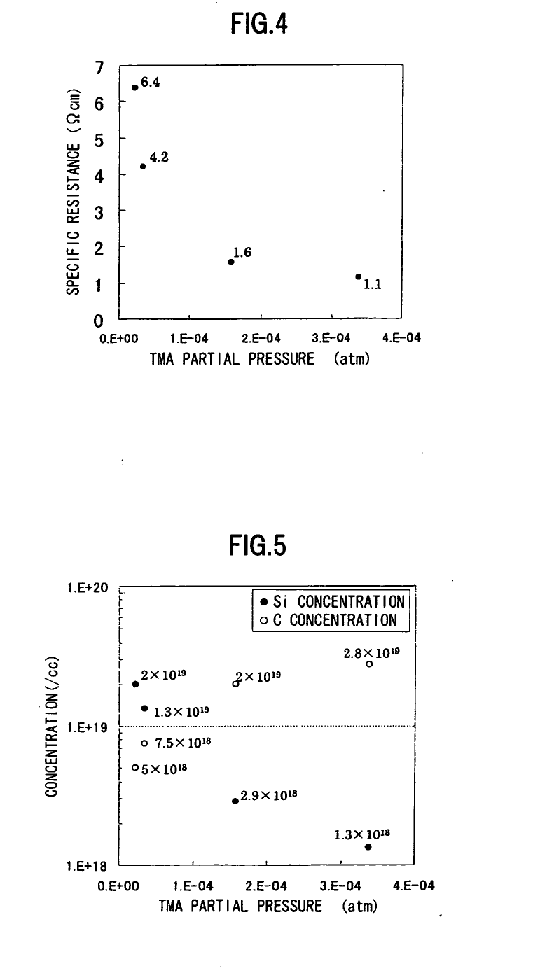

FIG. 3 shows a relationship between a TMA partial pressure and a growth rate of AlN which was obtained by changing an NH₃ partial pressure was controlled to be 5×10⁻² atm and a bubbling flow rate of TMA. Here, a pressure of HCl to be mixed with TMA and supplied was controlled to be the same as the TMA partial pressure. The specific resistance of the crystal thus obtained was measured by a four point probe method. FIG. 4 shows the measurement result. The specific resistance was lowered in accordance with the increase in the growth rate. Next. P/N determination was conducted by a hot probe method. As a result. it is confirmed that the p-type conductivity was observed in all samples. FIG. 5 shows a result of a SIMS (Secondary Ion Mass Spectrometer) analysis. It is observed that the Si concentration is decreased in accordance with the increase in the growth rate and that the C concentration is increased in accordance with the increase in the growth rate.

Under the condition of the highest growth rate, an AlN crystal having a thickness of 10 mm was grown. The growth was successfully completed without having the ventilation system or a filter blocked, and without having a quartz component to be eroded

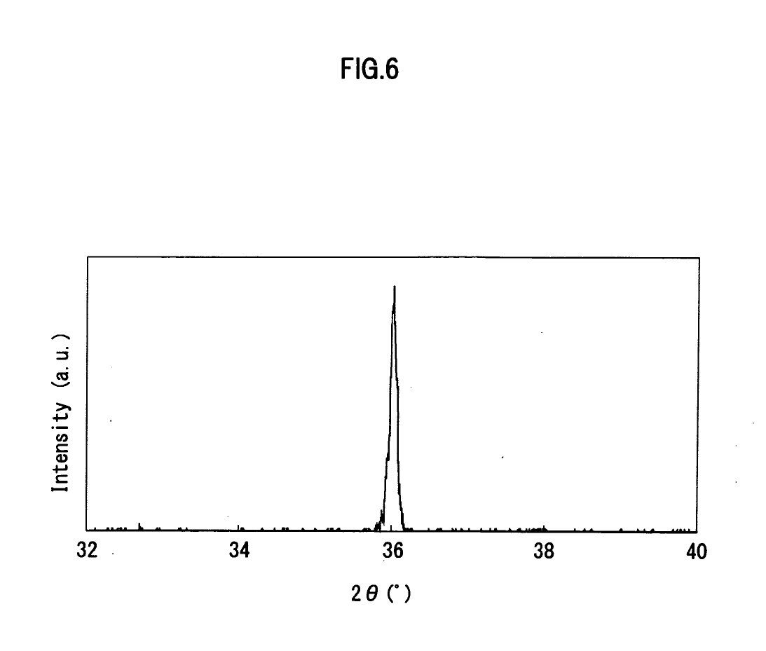

Next, FIG. 6 shows the result of a so-called θ-2θ measurement in the range of 2θ=32° to 40°.

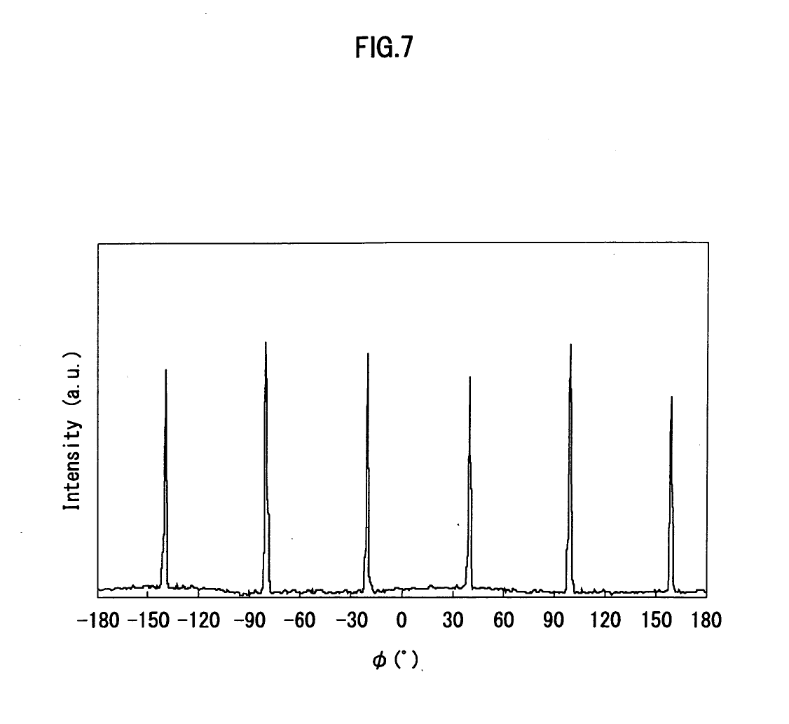

In the measurement range of X-ray diffraction measurement, only a diffraction peak in AlN (0002) was observed. As a result, it is confirmed that the AlN (0002) plane was c-axis oriented. FIG. 7 shows a result of φ scan of (10-11) plane of the AlN crystal. As a result, hexagonal symmetry in the crystal plane (10-11) was confirmed. From the above result, it is confirmed that the AlN single crystal was obtained. By cutting the AlN single crystal with a multi-wire saw to be 0.6 mm in thickness, and by polishing front and back surfaces, to provide 12 pieces of the AlN single crystal substrate having a diameter of 2 inches.

### Example 1b

A growth of a group III nitride crystal was conducted by using the HVPE apparatus shown in FIG. 1. TMA was used as the organic metal source material 14 of Al. The temperature of the constant temperature reservoir 15 was set to be 19° C. TMA was bubbled by N₂ as a bubbling gas 12, and mixed with HCl gas 11. Thereafter, the mixed gas was conveyed by the carrier gas 10 to a growth region. N₂ was used for the carrier gas 10 of a TMA+HCl line. A growth pressure was set to be the normal pressure.

Only the carrier gas 2 (N₂) was supplied onto the Ga melt 17. Here, the temperature of the source material generating unit (i.e. the temperature of the Ga melt 17) was set to be 850° C.

In the growth region, an Al source material and the ammonia gas 1 were mixed on a c-plane sapphire substrate 6 (a diameter of 2 inches) mounted on the susceptor 7 made of graphite and heated at 1000° C. so that the AlN crystal (a diameter of 2 inches) was grown on the substrate 6. Herein, an NH₃ partial pressure was set to be 5×10⁻² atm and a bubbling flow rate of TMA was changed. Here, a pressure of HCl to be mixed with TMA and supplied was controlled to be the same as the TMA partial pressure.

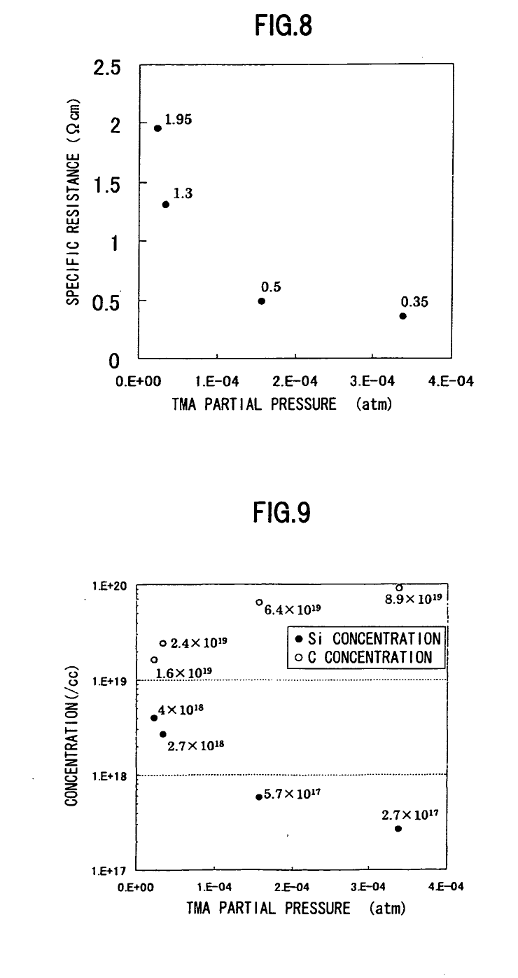

The specific resistance of the crystal thus obtained was measured by a four point probe method. FIG. 8 shows the measurement result. The specific resistance was further lowered compared with Example 1. Next, P/N determination was conducted by a hot probe method. As a result, it is confirmed that the p-type conductivity was observed in all samples. FIG. 9 shows a result of a SIMS analysis. It is observed that the Si concentration is further decreased compared with Example 1 and that the C concentration is further increased compared with Example 1. It is supposed that degassing from quartz was decreased due to the low-temperature growth, and that elimination of C from the group III source material was decreased.

### Example 1c

A growth of a group III nitride crystal was conducted by using the HVPE apparatus shown in FIG. 1. TMA was used as the organic metal source material 14 of Al. The temperature of the constant temperature reservoir 15 was set to be 19° C. TMA was bubbled by N₂ as a bubbling gas 12, and mixed with HCl gas 11. Thereafter, the mixed gas was conveyed by the carrier gas 10 to a growth region. H₂ was used for the carrier gas 10 of a TMA+HCl line. A growth pressure was set to be the normal pressure.

Only the carrier gas 2 (H₂) was supplied onto the Ga melt 17. Here, the temperature of the source material generating unit (i.e. the temperature of the Ga melt 17) was set to be 850° C.

In the growth region, an Al source material and the ammonia gas 1 were mixed on a c-plane sapphire substrate 6 (a diameter of 2 inches) mounted on the susceptor 7 made of graphite and heated at 1100° C., so that the AlN crystal (a diameter of 2 inches) was grown on the substrate 6. Herein, an NH₃ partial pressure was set to be 5×10⁻² atm and a bubbling flow rate of TMA was changed. Here, a pressure of HCl to be mixed with TMA and supplied was controlled to be the same as the TMA partial pressure.

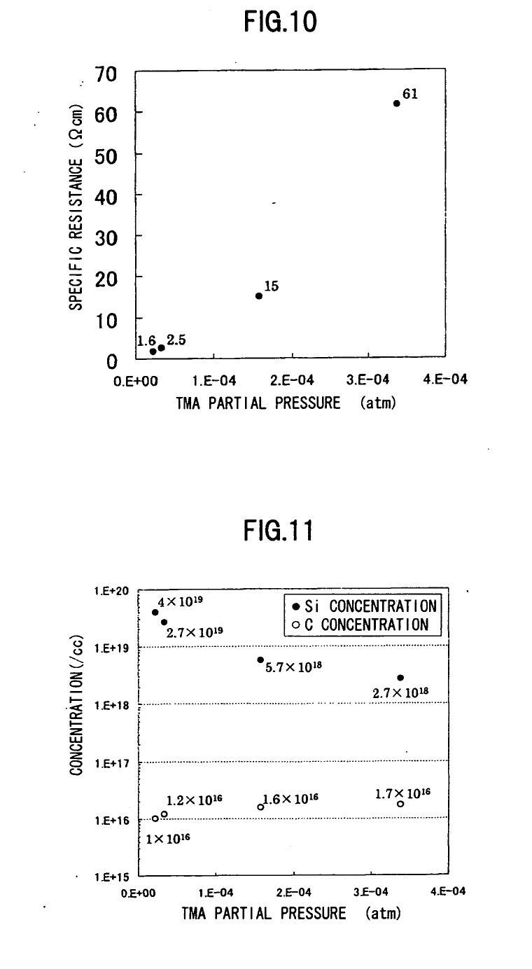

The specific resistance of the crystal thus obtained was measured by a four point probe method. FIG. 10 shows the measurement result. Next, P/N determination was conducted by a hot probe method. As a result, it is confirmed that the n-type conductivity was observed in all samples. FIG. 11 shows a result of a SIMS analysis. It is observed that the C concentration was decreased by two digits compared with Example 1. It is supposed that there was elimination of C due to hydrogen.

### Example 1d

A growth of a group III nitride crystal was conducted by using the HVPE apparatus shown in FIG. 1. TMA was used as the organic metal source material 14 of Al. The temperature of the constant temperature reservoir 15 was set to be 19° C. TMA was bubbled by N₂ as a bubbling gas 12, and mixed with HCl gas 11. Thereafter, the mixed gas was conveyed by the carrier gas 10 to a growth region. H₂ was used for the carrier gas 10 of a TMA+HCl line. A growth pressure was set to be the normal pressure.

Only the carrier gas 2 (H₂) was supplied onto the Ga melt 17. Here, the temperature of the source material generating unit (i.e. the temperature of the Ga melt 17) was set to be 850° C.

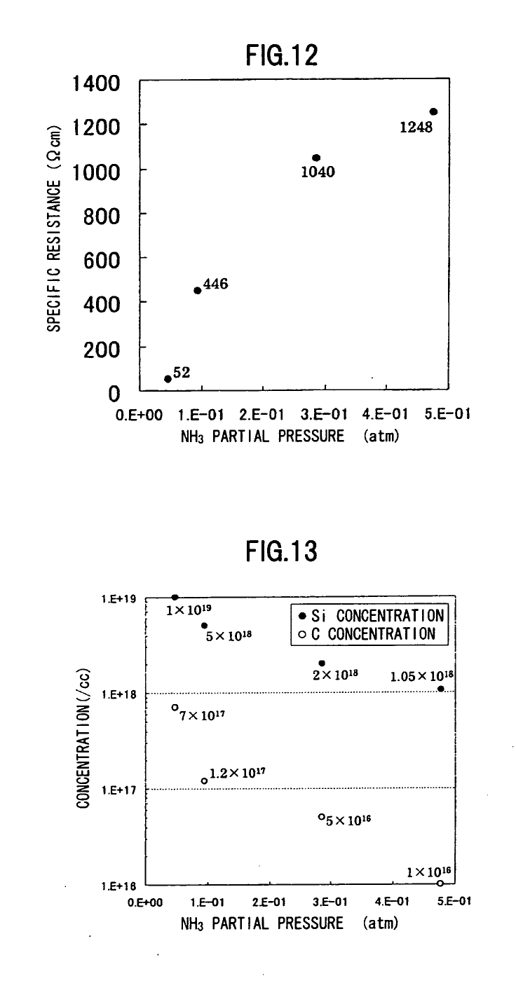

In the growth region, an Al source material and the ammonia gas 1 were mixed on a c-plane sapphire substrate 6 (a diameter of 2 inches) mounted on the susceptor 7 made of graphite and heated at 1050° C., so that the AlN crystal (a diameter of 2 inches) was grown on the substrate 6. Herein, a TMA partial pressure was set to be 2.26×10⁻⁵ atm. A pressure of HCl to be mixed with TMA and supplied was controlled to be the same as the TMA partial pressure. The specific resistance of the crystal grown by changing NH₃ partial pressured was measured by a four point probe method. FIG. 12 shows the measurement result. The semi-insulation property was realized by conducting the crystal growth under a high NH₃ pressure. FIG. 13 shows a result of a SIMS analysis of the crystal obtained in Example 1d.

### Example 1e

Be, Mg, Cd, Zn, and Hg concentration in the crystal obtained in Examples 1a to 1d were examined by SIMS analysis. The concentration of each impurity in all the crystals was not greater than the minimum limit value of detection.

### Example 2a

In Example 2a, a growth of an AlₓGa₁₋ₓN crystal was conducted by using the HVPE apparatus shown in FIG. 1. TMA was used as the organic metal source material 14 of Al. The temperature of the constant temperature reservoir 15 was set to be 19° C. TMA was bubbled by N₂ as a bubbling gas 12, and mixed with HCl gas 11. Thereafter, the mixed gas was conveyed by the carrier gas 10 to a growth region. A H₂N₂ mixed gas was used for the carrier gas 10 of a TMA+HCl line.

In the case of growing the AlₓGa₁₋ₓN crystal (0<x≦1), the temperature of a source material generating region was set to be 850° C. Then, hydrogen halide gas+carrier gas 2 was flown onto a surface of a Ga melt 17 to make the hydrogen halide gas contact with the Ga melt 17, thereby GaCl was generated and conveyed to a growth region by the carrier gas 2. H₂/N₂ mixed gas was used for carrier gas 2. In the case of growing an AlN crystal, only the carrier gas 2 was flown.

In the growth region, the group III source material and the ammonia gas 1 were mixed on a c-plane sapphire substrate 6 mounted on the susceptor 7 made of graphite and heated at 1100° C., so that the AlₓGa₁₋ₓN crystal (0<x≦1) crystal was grown on the substrate 6.

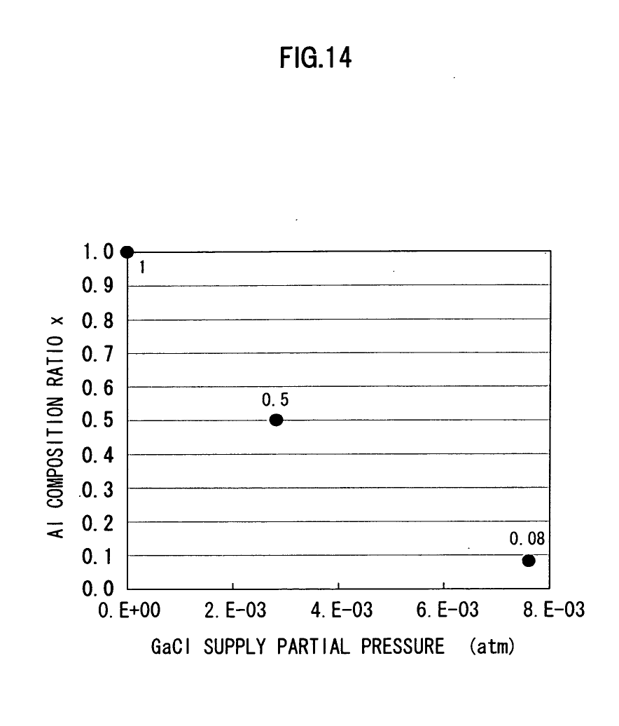

While controlling a supply partial pressure of TMA to be 2.3×10⁻⁵ atm, a partial pressure of HCl to be mixed with TMA and supplied to be 2.3×10⁻⁴ atm, an NH₃ partial pressure to be 5×10⁻² atm and H₂ partial pressure to be 0.1 atm, a supply partial pressure of GaCl was changed from 0 atm to 7.6×10⁻³ atm. FIG. 14 shows the change of the Al composition ratio x of the AlₓGa₁₋ₓN crystal. Herein, the Al composition ratio x of the AlₓGa₁₋ₓN crystal was calculated from the result of θ-2θ measurement of the X-ray diffraction measurement.

### Example 2b

It is confirmed that the specific resistance and the electrical conductivity in the AlₓGa₁₋ₓN crystal (0<x≦1) manufactured as in Example 2a can also be controlled with the same idea as in Examples 1a to 1d. The reduction in resistance is made easier in accordance with the increase in the Ga composition ratio.

### Example 3

In Example 3, a plurality of sapphire substrates were prepared for samples. An AlₓGa₁₋ₓN (0<x≦1) buffer layer having a film thickness of 60 nm was formed on each sapphire substrate with the pressures of the respective source materials used in each of Examples 1 (1a to 1d) and 2 (2a and 2b). Thereafter, a supply of HCl gas 11 mixed with bubbling of TMA and TMA was stopped. Successively, a GaN layer as a second group III nitride semiconductor layer was grown on the buffer layer for six minutes in each sample, while controlling the GaCl supply partial pressure to be 2.85×10⁻³ atm. the NH₃ partial pressure to be 5×10⁻² atm and the H₂ pressure to be 0.1 atm. A growth temperature (a temperature of the susceptor 7) was controlled to be 1050° C. According to this process, a GaN template having a thickness of 8 μm and a diameter of 2 inches was obtained for each sample.

### Example 4

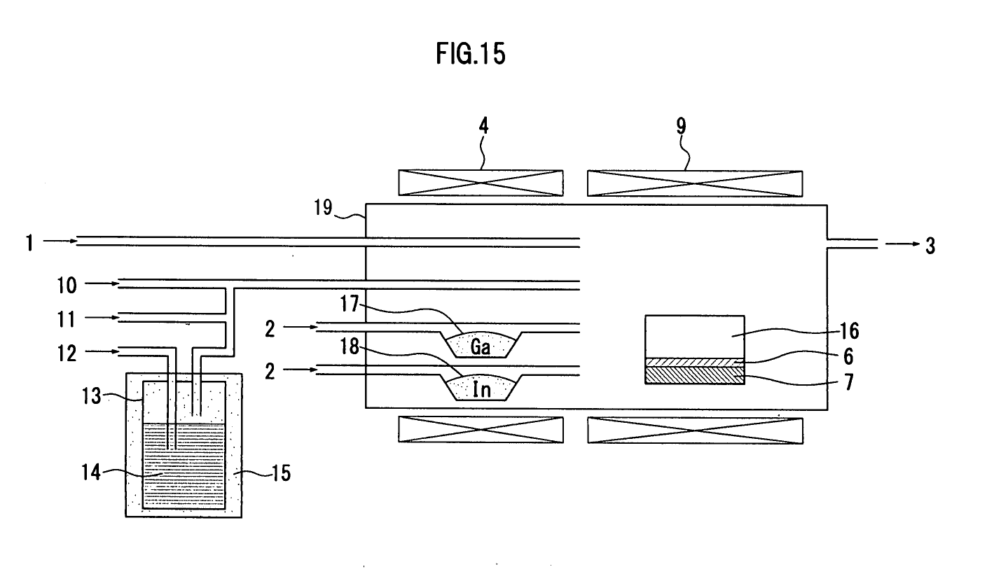

In Example 4, referring to FIG. 15, a boat made of quartz for containing an In melt 18 was inserted into the HVPE growth apparatus as shown in FIG. 1. Samples of InN template were manufactured using the HVPE growth apparatus as shown in FIG. 15. A plurality of sapphire substrates were prepared for samples. AlₓGa₁₋ₓN (0<x≦1) buffer layer having a film thickness of 60 nm was formed on each sapphire substrate with the pressures of the respective source materials used in each of Examples 1 (1a to 1d) and 2 (2a and 2b). Thereafter, a supply of source materials except NH₃ was stopped. After lowering the temperature of the growth region (the temperature of the susceptor 7) to 700° C., an InN layer as a second group III nitride semiconductor layer was grown on the buffer layer for six minutes in each sample, while controlling the InCl supply partial pressure to be 2.85×10⁻² atm and the NH₃ partial pressure to be 5×10⁻² atm. At this time, N₂ was used as a carrier gas 2. As a result, the InN template having a thickness of 8 μm and a diameter of 2 inches was obtained for each sample.

### Example 5

Samples of AlₓIn_{y}Ga_{1-x-y}N (0≦x≦1, 0≦y≦1, 0≦x+y≦1) template were manufactured using the HVPE growth apparatus as shown in FIG. 15. A plurality of sapphire substrates were prepared for samples. An AlₓGa₁₋ₓN (0<x≦1) buffer layer having a film thickness of 60 nm was formed on each sapphire substrate with the pressures of the respective source materials used in each of Examples 1 (1a to 1d) and 2 (2a and 2b). Thereafter, a supply of source materials except NH₃ was stopped. After lowering the temperature of the growth region (the temperature of the susceptor 7) to 700° C., an AlₓIn_{y}Ga_{1-x-y}N (0≦x≦1, 0≦y≦1, 0≦x+y≦1) layer as a second group III nitride semiconductor layers was grown on the buffer layer for six minutes in each sample. It is confirmed that the AlₓIn_{y}Ga_{1-x-y}N (0≦x≦1, 0≦y≦1, 0≦x+y≦1) template with any arbitrary composition was grown by controlling the GaCl partial pressure, the InCl partial pressure and the TMA partial pressure appropriately.

### Example 6

Experiments similar to Examples 1 to 5 were conducted using HBr or HI instead of HCl. Approximately the same result was obtained as in the case of using HCl.

### Example 7

Experiments similar to Examples 1 to 6 were conducted by replacing the support substrate 6 with a silicon carbide. Approximately the same result was obtained.

### Example 8

Experiments similar to Examples 1 to 7 were conducted by replacing the carrier gas NI, with Ar or He. Approximately the same result was obtained.

### Example 9

Experiments similar to Examples 1 to 8 were conducted by changing the temperature of the source material generating region from 700° C. to 1100° C., approximately the same result was obtained.

Although the invention has been described with respect to the specific embodiment for complete and clear disclosure, the above embodiments and examples are not to be limited thereto. Further, it should be noted that all the combinations of the technical features described in embodiments or examples are not necessarily essential to means to solve the problems of the invention.

What is claimed is:

1. A method for manufacturing a group III nitride crystal, comprising:
mixing a group III source material and ammonia in a reactor comprising quartz; and
growing a group III nitride crystal on a support substrate by a vapor deposition,
wherein the group III source material comprises an organic metal source material containing Al, and the organic metal source material is mixed with a hydrogen halide gas and supplied to the reactor.

2. The method for manufacturing a group III nitride crystal according to claim 1, wherein the organic metal source material containing Al comprises trimethyl aluminum.

3. The method for manufacturing a group III nitride crystal according to claim 1, wherein the hydrogen halide gas is selected from the group consisting of a hydrogen chloride, a hydrogen bromide and a hydrogen iodide.

4. The method for manufacturing a group III nitride crystal according to claim 1,
wherein the support substrate comprises a single crystal substrate comprising a single crystal of a material selected from the group consisting of a sapphire, a silicon, a silicon carbide and a gallium nitride.

5. A method for manufacturing a group III nitride template, comprising:
forming the group III nitride crystal as a buffer layer by the method according to claim 1, and
forming a second group III nitride semiconductor layer on the buffer layer.

6. The method for manufacturing a group III nitride template, according to claim 5, wherein the second group III nitride semiconductor layer comprises a composition of AlₓIn_{y}Ga_{1-x-y}N (0≦x≦1, 0≦y≦1, 0≦x+y≦1).

7. A group III nitride crystal, comprising:
carbon of 1×10¹⁶ cm⁻³ or more and less than 1×10²⁰ cm⁻³ in the group III nitride crystal,
wherein the carbon replaces a group V site,
wherein other impurities acting as an acceptor in the group III nitride crystal is not contained.

8. A group III nitride template, comprising:
a support substrate;
a buffer layer formed on the support substrate, the buffer layer comprising the III group nitride crystal according to claims 7; and
a second group III nitride semiconductor layer formed on the buffer layer.

9. The group III nitride template according to claim 8, wherein the second group III nitride semiconductor layer comprises a composition of AlₓIn_{y}Ga_{1-x-y}N (0≦x≦1, 0≦y≦1, 0≦x+y≦1).
